(19) United States
(12) Patent Application Publication
(10) Pub. No.: US 2026/0333936 A1
(43) Pub. Date: Oct. 22, 2026

(54) LIGHT RECEIVING ELEMENT AND METHOD OF MANUFACTURING THE SAME

(71) Applicant: SUMITOMO ELECTRIC INDUSTRIES, LTD., Osaka (JP)

(72) Inventor: Ryo SUGAHARA, Osaka (JP)

(73) Assignee: SUMITOMO ELECTRIC INDUSTRIES, LTD., Osaka (JP)

(21) Appl. No.: 19/640,466

(22) Filed: Apr. 7, 2026

(30) Foreign Application Priority Data
Apr. 16, 2025 (JP) 2025-067508

(51) Int. Cl. H10F 77/14; H10F 30/225

(52) U.S. Cl. CPC H10F 77/147; H10F 30/225

(57) ABSTRACT

A light receiving element includes a first semiconductor layer having a first conductivity type, a second semiconductor layer stacked on the first semiconductor layer and having a second conductivity type, a light-absorbing layer provided between the first semiconductor layer and the second semiconductor layer, a multiplication layer provided between the first semiconductor layer and the second semiconductor layer, and a first electric field control layer provided between the light-absorbing layer and the second semiconductor layer and between the multiplication layer and the second semiconductor layer, and having the second conductivity type. The first electric field control layer is formed of the same material as the second semiconductor layer. The second semiconductor layer forms a first mesa. At least a part of the first electric field control layer in a thickness direction and the light-absorbing layer form a second mesa.

### CROSS REFERENCE TO RELATED APPLICATIONS

This application claims priority based on Japanese Patent Application No. 2025-067508 filed on Apr. 16, 2025, and the entire contents of the Japanese patent application are incorporated herein by reference.

### TECHNICAL FIELD

The present disclosure relates to a light receiving element and a method of manufacturing the same.

### BACKGROUND

A mesa may be formed in the light receiving element (for example, Patent Literature 1: WO 2008/090733).

### SUMMARY

A light receiving element according to the present disclosure includes a first semiconductor layer having a first conductivity type, a second semiconductor layer stacked on the first semiconductor layer and having a second conductivity type, a light-absorbing layer provided between the first semiconductor layer and the second semiconductor layer, a multiplication layer provided between the first semiconductor layer and the second semiconductor layer, and a first electric field control layer provided between the light-absorbing layer and the second semiconductor layer and between the multiplication layer and the second semiconductor layer, and having the second conductivity type. The first electric field control layer is formed of the same material as the second semiconductor layer. The second semiconductor layer forms a first mesa. At least a part of the first electric field control layer in a thickness direction and the light-absorbing layer form a second mesa. The second mesa protrudes from the first semiconductor layer in the thickness direction. The first mesa protrudes from the second mesa in the thickness direction. The second mesa is located below the first mesa and has a side surface located outside the first mesa in a plan view.

### BRIEF DESCRIPTION OF THE DRAWINGS

FIG. 1A is a plan view illustrating a light receiving element according to a first embodiment.

FIG. 1B is a cross-sectional view illustrating a light receiving element.

FIG. 2A is a cross-sectional view illustrating a method of manufacturing a light receiving element.

FIG. 2B is a cross-sectional view illustrating a method of manufacturing a light receiving element.

FIG. 2C is a cross-sectional view illustrating a method of manufacturing a light receiving element.

FIG. 3A is a cross-sectional view illustrating an electric field.

FIG. 3B is a cross-sectional view illustrating an electric field.

FIG. 4A is a diagram illustrating an electric field profile.

FIG. 4B is a diagram illustrating an electric field profile.

FIG. 5 is a cross-sectional view illustrating a light receiving element according to a modification 1.

FIG. 6A is a plan view illustrating a light receiving element according to a second embodiment.

FIG. 6B is a cross-sectional view illustrating a light receiving element.

### DETAILED DESCRIPTION

In the step of forming the mesa, the semiconductor layer may be wet-etched. In wet etching, etching selectivity may be utilized to stop etching at a desired depth. In order to perform selective etching, an appropriate material and an etchant are used. For example, semiconductor layers having different compositions, such as an arsenic (As)-based semiconductor layer and a phosphorus (P)-based semiconductor layer, are stacked, and a mixed solution of phosphoric acid and hydrogen peroxide water is used as an etchant. In this case, the As-based semiconductor layer is etched, and the P-based semiconductor layer is not etched. Thus, the etching is stopped at the upper surface of the P-based semiconductor layer. However, when materials are stacked in consideration of etching selectivity, lattice distortion is likely to occur. Further, since etching has anisotropy depending on a crystal plane, an inverted mesa may be formed. In the inverted mesa shape, the electric field tends to concentrate locally. These factors may increase the dark current. Thus, an object of the present disclosure is to provide a light receiving element capable of reducing a dark current and a method of manufacturing the same.

According to the present disclosure, it is possible to provide a light receiving element capable of reducing a dark current and a method of manufacturing the same.

### DESCRIPTION OF EMBODIMENTS OF PRESENT DISCLOSURE

The contents of the embodiments of the present disclosure will be listed and described first.
(1) A light receiving element according to an aspect of the present disclosure includes a first semiconductor layer having a first conductivity type, a second semiconductor layer stacked on the first semiconductor layer and having a second conductivity type, a light-absorbing layer provided between the first semiconductor layer and the second semiconductor layer, a multiplication layer provided between the first semiconductor layer and the second semiconductor layer, and a first electric field control layer provided between the light-absorbing layer and the second semiconductor layer and between the multiplication layer and the second semiconductor layer, and having the second conductivity type. The first electric field control layer is formed of the same material as the second semiconductor layer. The second semiconductor layer forms a first mesa. At least a part of the first electric field control layer in a thickness direction and the light-absorbing layer form a second mesa. The second mesa protrudes from the first semiconductor layer in the thickness direction. The first mesa protrudes from the second mesa in the thickness direction. The second mesa is located below the first mesa and has a side surface located outside the first mesa in a plan view. Since the first electric field control layer is formed of the same material as the second semiconductor layer, lattice distortion is less likely to occur. The electric field is confined by the first mesa. The electric field applied to the side surface of the second mesa is lowered. Thus, the dark current may be reduced. Abnormal breakdown may be avoided.
(2) In the above (1), a part of the first electric field control layer in the thickness direction and the second semiconductor layer may form the first mesa. Another part of the first electric field control layer in the thickness direction and the light-absorbing layer may form the second mesa. The electric field is confined by the first mesa. The electric field applied to the side surface of the second mesa is lowered. A dark current may be reduced and abnormal breakdown may be avoided.
(3) In the above (1) or (2), the semiconductor device may include a second electric field control layer having the first conductivity type. The second electric field control layer, the multiplication layer, and the first electric field control layer may be stacked in this order between the light-absorbing layer and the second semiconductor layer. The light-absorbing layer, the second electric field control layer, the multiplication layer, and the at least a part of the first electric field control layer, may form the second mesa. The electric field is confined by the first mesa. The electric field applied to the side surface of the second mesa is lowered. A dark current may be reduced and abnormal breakdown may be avoided. A high electric field is applied to the multiplication layer, carriers are accelerated, and avalanche breakdown occurs. Sensitivity is improved.
(4) In any one of the above (1) to (3), the first electric field control layer may have a doping concentration of 1.0×10¹⁸ cm⁻³ or less. The entire first electric field control layer is depleted. The electric field is then confined by the first mesa. A dark current may be reduced and abnormal breakdown may be avoided.
(5) In any one of the above (1) to (4), the first electric field control layer may have a thickness that is 0.06 or more times a thickness from an upper surface of the second semiconductor layer to a center of the first electric field control layer in the thickness direction. The stop position of etching is easily controlled. The first mesa may be formed by stopping the etching in the middle of the first electric field control layer. It is possible to avoid lattice distortion and achieve the confining of the electric field by the first mesa. A selective etchant is not required to be used for stopping etching. An etchant with small anisotropy may be used for etching the second semiconductor layer and the first electric field control layer. The first mesa may be avoided from having an inverted mesa shape.
(6) In any one of the above (1) to (5), the first conductivity type may be a p-type. The second conductivity type may be an n-type. A nip junction is formed, and the first mesa and the second mesa are depleted in response to the application of a voltage. A high electric field is applied to the multiplication layer, and carriers are accelerated. Avalanche breakdown occurs, and the sensitivity is improved. Since the electric field is confined by the first mesa, the dark current may be reduced and abnormal breakdown may be avoided.
(7) In the above (1) or (2), the semiconductor device may further include a third electric field control layer having the second conductivity type. The multiplication layer and the third electric field control layer may be stacked in this order between the first semiconductor layer and the light-absorbing layer. The first electric field control layer may be provided between the light-absorbing layer and the second semiconductor layer. At least a part of the third electric field control layer and the multiplication layer may form a third mesa. The second mesa may protrude from the third mesa in the thickness direction. The third mesa may be located below the second mesa and may have a side surface located outside the second mesa in a plan view. The electric field is confined by the second mesa. The multiplication layer is included in the third mesa, and an electric field applied to the side surface is lowered. Abnormal breakdown may be avoided.
(8) In the above (7), a part of the third electric field control layer in the thickness direction, the light-absorbing layer, and the at least a part of the first electric field control layer may form the second mesa. Another part of the third electric field control layer in the thickness direction and the multiplication layer may form the third mesa. The electric field is confined by the second mesa. The multiplication layer is included in the third mesa, and an electric field applied to the side surface is lowered. Abnormal breakdown may be avoided.
(9) In the above (7) or (8), the first conductivity type may be an n-type. The second conductivity type may be a p-type. A high electric field is applied to the multiplication layer, and carriers are accelerated. Avalanche breakdown occurs, and the sensitivity is improved. Since the electric field is confined by the first mesa, the dark current may be reduced and abnormal breakdown may be avoided.
(10) A method of manufacturing a light receiving element includes growing a first semiconductor layer, a light-absorbing layer, a multiplication layer, an electric field control layer, and a second semiconductor layer, forming a first mesa by etching the second semiconductor layer, and forming a second mesa by etching the electric field control layer and the light-absorbing layer. The first semiconductor layer has a first conductivity type. The electric field control layer and the second semiconductor layer each have a second conductivity type. The electric field control layer is provided between the light-absorbing layer and the second semiconductor layer and between the multiplication layer and the second semiconductor layer, and is formed of the same material as the second semiconductor layer. The second semiconductor layer forms the first mesa. At least a part of the electric field control layer in a thickness direction and the light-absorbing layer form the second mesa. The first mesa protrudes from the second mesa in the thickness direction. The second mesa is located below the first mesa and has a side surface located outside the first mesa in a plan view. Since the first electric field control layer is formed of the same material as the second semiconductor layer, lattice distortion is less likely to occur. The electric field is confined by the first mesa. The electric field applied to the side surface of the second mesa is lowered. Thus, the dark current may be reduced. Abnormal breakdown may be avoided. A selective etchant is not required to be used for stopping etching. An etchant with small anisotropy may be used for etching of the second semiconductor layer and the electric field control layer. The first mesa may be avoided from having an inverted mesa shape.

### DETAILS OF EMBODIMENTS OF PRESENT DISCLOSURE

Specific examples of a light receiving element and a method of manufacturing the same according to an embodiment of the present disclosure will be described below with reference to the drawings. The present disclosure is not limited to these examples, but is defined by the scope of the claims, and is intended to include all modifications within the meaning and scope equivalent to the scope of the claims.

### First Embodiment

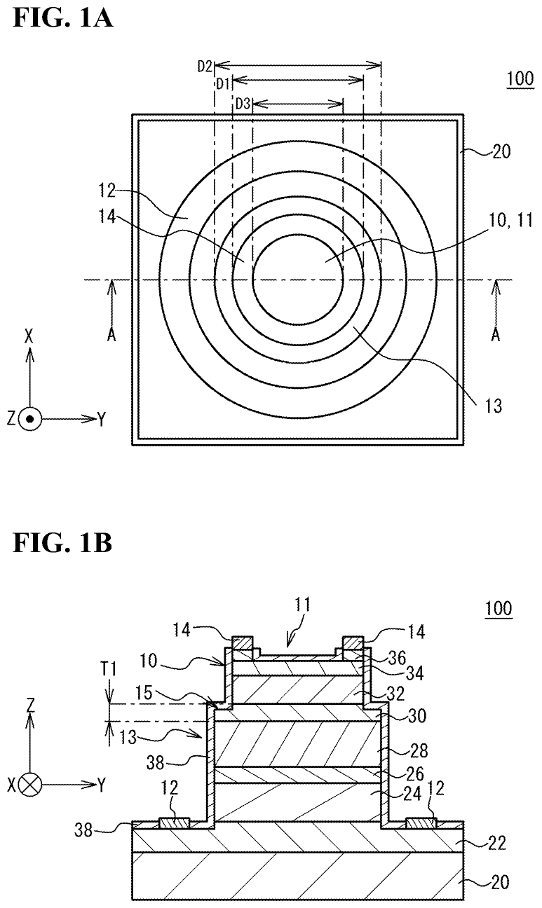

FIG. 1A is a plan view illustrating a light receiving element 100 according to a first embodiment. An insulating film described later is shown in a see-through manner. FIG. 1B is a cross-sectional view illustrating the light receiving element 100 and showing the cross section taken along line A-A of FIG. 1A. The light receiving element 100 is an avalanche photodiode (APD), and is used for detecting infrared light, for example.

As shown in FIG. 1A, the light receiving element 100 includes a mesa 10 (first mesa), a mesa 13 (second mesa), an electrode 12, an electrode 14, and a substrate 20. The planar shape of the substrate 20 is, for example, a square. The upper surface of the substrate 20 is parallel to the XY plane. The length of one side of the substrate 20 is, for example, 400 μm. A Z axis is the thickness direction of the substrate 20. An X axis, a Y axis, and the Z axis are orthogonal to each other.

In the plan view, the mesa 10 and the mesa 13 are circular. The mesa 10 and the mesa 13 are arranged concentrically, for example. The mesa 13 is larger than the mesa 10 and is located below mesa 10 and outside mesa 10. In the plan view, the mesa 10 is located inside the mesa 13. A diameter D1 of the mesa 10 is, for example, 240 μm. A diameter D2 of the mesa 13 is, for example, 280 μm.

The electrode 12 and the electrode 14 have, for example, an annular shape. The electrode 14 is provided in the mesa 10. A portion of the mesa 10 inside the electrode 14 functions as a light receiving region 11. A diameter D3 of the light receiving region 11 is, for example, 200 μm. The electrode 12 is provided outside the mesa 10 and the mesa 13 and surrounds the mesa 10 and the mesa 13.

As shown in FIG. 1B, the light receiving element 100 includes the substrate 20, a contact layer 22 (first semiconductor layer), a light-absorbing layer 24, an electric field control layer 26 (second electric field control layer), an electron multiplication layer 28, an electric field control layer 30 (first electric field control layer), a window layer 32 (second semiconductor layer), a window layer 34 (second semiconductor layer), and a contact layer 36.

The contact layer 22 is provided on the upper surface of the substrate 20. The central portion of the contact layer 22 in the XY plane protrudes in the Z-axis direction from the outer peripheral portion of the contact layer 22. The light-absorbing layer 24, the electric field control layer 26, the electron multiplication layer 28, and the electric field control layer 30 are stacked in this order in the central portion of the contact layer 22. The central portion of the electric field control layer 30 protrudes in the Z-axis direction from the outer peripheral portion of the electric field control layer 30. The window layer 32 and the window layer 34 are stacked on the protruding portion of the electric field control layer 30. The window layer 32 is in contact with one surface of the electric field control layer 30. The ring-shaped contact layer 36 is provided on the upper surface of the window layer 34.

A portion of the electric field control layer 30 protruding in the Z-axis direction, the window layer 32, and the window layer 34 form the mesa 10. The mesa 13 is formed by the protruding portion of the contact layer 22, the light-absorbing layer 24, the electric field control layer 26, the electron multiplication layer 28, and a part of the electric field control layer 30 in the Z-axis direction. A step portion 15 is formed in the electric field control layer 30 between the mesa 10 and the mesa 13. The step portion 15 is a boundary between the mesa 10 and the mesa 13.

An insulating film 38 covers the upper surface of the contact layer 22, the side surface of the mesa 13, the step portion 15, and the side surface and the upper surface of the mesa 10. The insulating film 38 has an opening on the upper surface of the mesa 10. The contact layer 36 is provided in the opening. The electrode 14 has a ring shape and is electrically connected to the contact layer 36. An opening is provided in a portion of the insulating film 38 covering the upper surface of the contact layer 22. The electrode 12 is provided in the opening and is electrically connected to the contact layer 22.

The substrate 20 is formed of, for example, n-type (second conductivity type) indium phosphide (n-InP) and is roughened. The substrate 20 has a thickness of, for example, 500 μm. The n-type semiconductor such as the substrate 20 is doped with, for example, silicon (Si). The doping concentration of the substrate 20 is, for example, 1.0×10¹⁸ cm⁻³.

The contact layer 22 is formed of, for example, p-type (first conductivity type) indium gallium arsenide (p-InₓGa₁₋ₓAs, x=0.53). The contact layer 22 has a thickness of, for example, 1000 nm. The p-type semiconductor such as the contact layer 22 is doped with, for example, beryllium (Be). The doping concentration of the contact layer 22 is, for example, 1.0×10¹⁸ cm⁻³.

The light-absorbing layer 24 is formed of, for example, undoped InₓGa₁₋ₓAs (i-InₓGa₁₋ₓAs, x=0.53). The light-absorbing layer 24 has a thickness of, for example, 1000 nm. The doping concentration of the light-absorbing layer 24 is, for example, less than 1.0×10¹⁶ cm⁻³. The undoped semiconductor layers such as the light-absorbing layer 24 and the electron multiplication layer 28 are not intentionally doped.

The electric field control layer 26 is formed of, for example, p-In_{y}Al_{1-y}As (y=0.52). The electric field control layer 26 has a thickness of, for example, 200 nm. The doping concentration of the electric field control layer 26 is, for example, 1.7×10¹⁷ cm⁻³. The electron multiplication layer 28 is formed of, for example, undoped In_{y}Al_{1-y}As (y=0.52). The electron multiplication layer 28 has a thickness of, for example, the 300 nm. The doping concentration of the electron multiplication layer 28 is smaller than 1.0×10¹⁶ cm⁻³, for example. The electric field control layer 30 is formed of, for example, n-In_{y}Al_{1-y}As (y=0.52). A thickness T1 from a surface of the electric field control layer 30 in contact with the window layer 32 to a surface of the electric field control layer 30 in contact with the electron multiplication layer 28 is, for example, 200 nm. The doping concentration of the electric field control layer 30 is, for example, 1.7×10¹⁷ cm⁻³. The doping concentration of each layer may be changed depending on the magnitude of the voltage applied to the light receiving element 100, the thickness of the electric field control layer 30, and the like.

The electric field control layer 30, the window layer 32, and the window layer 34 are formed of the same material. The window layer 32 and the window layer 34 are formed of, for example, n-In_{y}Al_{1-y}As (y=0.52). The window layer 32 has a thickness of, for example, 600 nm. The doping concentration of the window layer 32 is, for example, 1.0×10¹⁶ cm⁻³. The window layer 34 has a thickness of, for example, 200 nm. The doping concentration of the window layer 34 is, for example, 1.0×10¹⁸ cm⁻³. The contact layer 36 is formed of, for example, n-InₓGa₁₋ₓAs (x=0.53). The contact layer 36 has a thickness of, for example, 200 nm. The doping concentration of the contact layer 36 is, for example, 1.0×10¹⁸ cm⁻³.

The insulating film 38 is a passivation film and is formed of an insulator such as silicon nitride (SiN). The insulating film 38 has a thickness of, for example, 100 nm to 1000 nm. The electrode 12 and the electrode 14 are formed of metal.

### Manufacturing Method

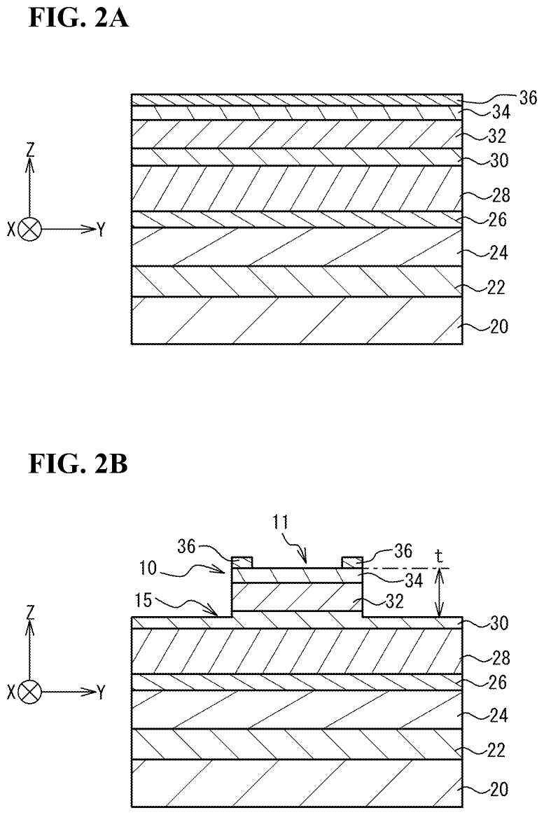

FIG. 2A to FIG. 2C are cross-sectional views illustrating a method of manufacturing the light receiving element 100. As shown in FIG. 2A, semiconductor layers from the contact layer 22 to the contact layer 36 are epitaxially grown in order on one surface of the substrate 20 by, for example, metal organic chemical vapor deposition (MOCVD). The surface of the substrate 20 is, for example, a (100) plane. The impurity may be added by supplying the impurity together with the source gas.

As shown in FIG. 2B, the contact layer 36 is processed and the mesa 10 is formed. First, a mask (not shown) is provided on the upper surface of the contact layer 36. The plane shape of the mask is a ring shape. Dry etching is performed using a mask to remove a portion of the contact layer 36 exposed from the mask. The contact layer 36 is processed into a ring shape. After the etching, the mask is removed by buffered hydrofluoric acid. The light receiving region 11 is formed in a portion surrounded by the contact layer 36.

The contact layer 36 and the light receiving region 11 are covered with a mask (not shown). Etching and removing are performed from the window layer 34 to the middle of the electric field control layer 30. The mesa 10 is formed. A part of the electric field control layer 30 extends out of the mesa 10 to form the step portion 15. The etching in this step may be performed from the upper surface of the window layer 34 to near the center of the Z-axis direction of the electric field control layer 30. The etching depth t from the upper surface of the window layer 34 is about 900 nm.

The mesa 13 is formed as shown in FIG. 2C. The upper surface of the mesa 10 and a portion of the electric field control layer 30 close to the mesa 10 are covered with a mask (not shown). The mask is circular, and the outer diameter of the mask is, for example, 250 μm. In the portion not covered with the mask, etching and removing are performed from the electric field control layer 30 to the middle of the contact layer 22. The mesa 13 is formed. After the etching, the mask is removed. The etching in the step of manufacturing the mesa 10 and the step of manufacturing the mesa 13 may be, for example, dry etching using silicon tetrachloride (SiCl₄) or wet etching using an etchant of an aqueous solution containing hydrobromic acid (HBr).

The insulating film 38 is deposited on the mesa 10, the mesa 13, and the contact layer 22 by, for example, a plasma-enhanced CVD. Openings are formed in a part of the insulating film 38 covering the contact layer 22 and a portion of the insulating film 38 covering the contact layer 36. The electrode 12 is formed on the contact layer 22 and the electrode 14 is formed on the contact layer 36 by vacuum deposition and lift-off. The light receiving element 100 is formed by the above steps.

The light receiving element 100 detects, for example, infrared light, and detects light having wavelengths in the 1550 nm. A negative-intrinsic-positive (nip) junction is formed in the light receiving element 100 along the Z-axis. A negative voltage is applied to the electrode 12. A positive voltage is applied to the electrode 14. The operating voltage is, for example, 20 V to 70 V. A depletion region extends in the mesa 10 and the mesa 13 in response to the application of the voltage. At a position overlapping the mesa 10 in plan view, the electric field control layer 26, the electron multiplication layer 28, and the electric field control layer 30 in the entire thickness direction are depleted. In the thickness direction, at least a part of the window layer 32 and the window layer 34 is also depleted. Infrared light enters from the light receiving region 11 and is absorbed by the light-absorbing layer 24. In response to light absorption, the light-absorbing layer 24 generates photocarriers (electron-hole pairs). The carriers are moved by an electric field applied to the depletion region and are output as a photocurrent.

The light receiving element 100 is an avalanche photodiode. By stacking the p-type electric field control layer 26, the electron multiplication layer 28, and the n-type electric field control layer 30 in this order, the electric field applied to the electron multiplication layer 28 may be increased. The electrons accelerated by the high electric field enter the electron multiplication layer 28, and avalanche breakdown occurs. That is, the electrons collide with the atoms in the electron multiplication layer 28, and thus more carriers are generated. This improves the sensitivity. Meanwhile, when a high electric field is applied to the side surface of the electron multiplication layer 28, abnormal breakdown may occur. When a high electric field is applied to the side surface of the light-absorbing layer 24, a dark current may increase.

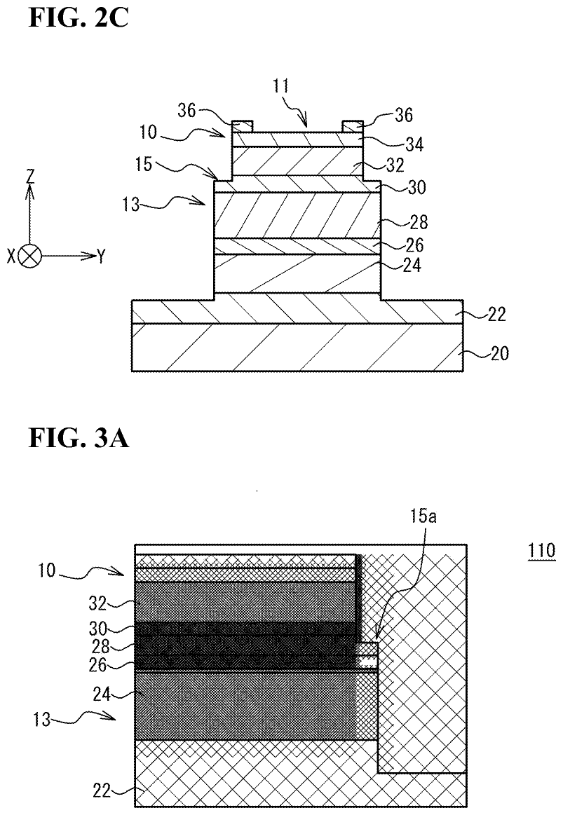

FIG. 3A and FIG. 3B are cross-sectional views illustrating an electric field, and showing near the one side surface which is a portion including a boundary between the mesa 10 and the mesa 13 of the light receiving element. The density of the lines represents the strength of the electric field. The portions with a high density of lines applies a strong electric field. The portions with a lower density of lines applies a lower electric field.

FIG. 3A illustrates a light receiving element 110 according to a comparative example. In the comparative example, the mesa 10 includes a part of the electron multiplication layer 28. The mesa 13 includes another part of the electron multiplication layer 28. A step portion 15a which is between the mesa 10 and the mesa 13 is formed in the electron multiplication layer 28. FIG. 3B shows the light receiving element 100 according to a first embodiment.

The electric field is then confined by the mesa 10. The electric field is high in a range substantially equal to the width of the mesa 10, and the electric field is low at a position outside the mesa 10. In the example of FIG. 3A, the mesa 10 includes a part of electron multiplication layer 28. The side surface of the electron multiplication layer 28 forms the side surface of the mesa 10, and a high electric field is applied to the side surface of the electron multiplication layer 28. In the example of FIG. 3B, the mesa 10 extends to a part of the electric field control layer 30 in the Z-axis direction and does not include the electron multiplication layer 28. The side surface of the electron multiplication layer 28 is located outside the mesa 10. Since the electric field is confined to the width of the mesa 10, the electric field applied to the side surface of the electron multiplication layer 28 is lowered.

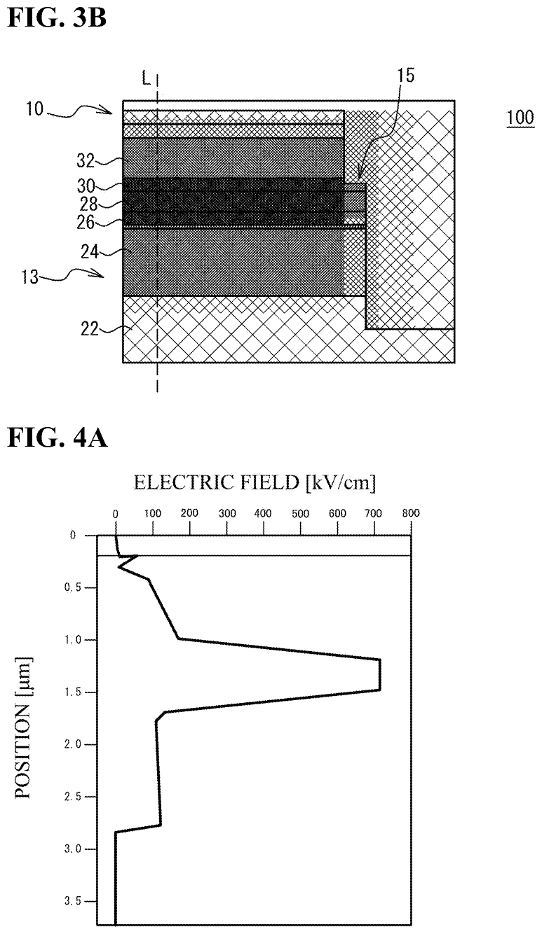

FIG. 4A and FIG. 4B are diagrams illustrating electric field profiles. FIG. 4A shows the electric field inside mesa 10 and the mesa 13, and shows the electric field at the position of a line L in FIG. 3B. The vertical axis represents the position along the Z axis. The horizontal axis represents the electric field. As shown in FIG. 4A, a high electric field is applied to the electron multiplication layer 28 inside the mesa 13.

FIG. 4B shows an electric field at a step portion. The horizontal axis represents the position in the X-axis direction. The 0 μm on the horizontal axis is the position of a specific point within the mesa 10. The 20 μm on the horizontal axis is the position of the side surface of the mesa 10. The vertical axis represents the electric field. The dotted line represents the calculation result of the electric field in the step portion 15a of the comparative example. The solid line represents the calculation result of the electric field in the step portion 15 of the first embodiment. As shown in FIG. 4B, the electric field in the comparative example is higher than the electric field in the first embodiment. In the comparative example, the electric field on the side surface is higher than 700 kV/cm. Abnormal breakdown is likely to occur. In the first embodiment, the electric field applied to the side surface is lower than 700 kV/cm. Abnormal breakdown is less likely to occur, and the dark current is reduced.

According to the first embodiment, the electric field control layer 30 is provided between the light-absorbing layer 24 and the electron multiplication layer 28, and the window layer 32. The electric field control layer 30 is formed of the same material as the window layer 32 and the window layer 34. Lattice distortion is less likely to occur, and the electric field control layer 30, the window layer 32, and the window layer 34 are lattice-matched. Thermal excitation of carriers is less likely to occur, and a dark current may be reduced.

The window layer 34, the window layer 32, and a part of the electric field control layer 30 form the mesa 10. Another part of the electric field control layer 30, the electron multiplication layer 28, the electric field control layer 26, the light-absorbing layer 24, and a part of the contact layer 22 form the mesa 13. In response to the application of the voltage, the semiconductor layers of the mesa 10 and the mesa 13 are depleted. In a plane parallel to the XY plane, the electric field is confined by the mesa 10. As shown in FIG. 4B, the electric field applied to the side surface of the mesa 13 is reduced to, for example, less than 700 kV/cm. Thus, the dark current may be reduced. An electric field applied to the side surface of the electron multiplication layer 28 is lowered, and abnormal breakdown may be avoided.

A p-type electric field control layer 26, the electron multiplication layer 28, and an n-type electric field control layer 30 are stacked between the light-absorbing layer 24 and the window layer 32. As shown in FIG. 4A, the electric field applied to the electron multiplication layer 28 is high near the center of the mesa of the light receiving element 100. Carriers are accelerated by the high electric field, avalanche breakdown occurs, and sensitivity is improved.

The doping concentration of the n-type dopant in the electric field control layer 30 may be 1.0×10¹⁸ cm⁻³ or less, 9.0×10¹⁷ cm⁻³ or less, 5.0×10¹⁷ cm⁻³ or less, or 1.0×10¹⁷ cm⁻³ or less, and may be 1×10¹⁵ cm⁻³ or more, 1×10¹⁶ cm⁻³ or more, or 5×10¹⁶ cm⁻³ or more. By setting the doping concentration to an appropriate value as described above, the entire electric field control layer 30 is depleted. As shown in FIG. 4A, the electric field of the electron multiplication layer 28 may be increased and the electric field of the light-absorbing layer 24 may be decreased. The carriers travel through the electric field control layer 30 and enter the electron multiplication layer 28 to which a high electric field is applied. Avalanche breakdown occurs, and the sensitivity is improved. The electron multiplication layer 28 is not included in the mesa 10. The electric field confined in the mesa 10 is not easily concentrated on the side surface of the electron multiplication layer 28. Abnormal breakdown is unlikely to occur.

The electric field control layer 30, the window layer 32, the window layer 34, and the contact layer 36 are n-type semiconductor layers. The light-absorbing layer 24 is an undoped semiconductor layer. The contact layer 22 and the electric field control layer 26 are p-type semiconductor layers. A nip junction is formed along the Z axis. A depletion region is generated in the light receiving element 100 in response to the application of the voltage. The carriers travel by the electric field and are output as a photocurrent. Near the center of the light receiving element 100, a high electric field is applied to the electron multiplication layer 28. Carriers are accelerated by the high electric field, and avalanche breakdown occurs. Sensitivity is improved. The electric field is confined by the mesa 10, and the electric field applied to the side surface of the mesa 13 is lowered. A dark current may be reduced and abnormal breakdown may be avoided.

The electric field control layer 30 is formed of the same material as the window layer 32 and the window layer 34. The etching rate of the electric field control layer 30 is substantially the same as the etching rate of the window layer 32. As shown in FIG. 2B, in the etching of the step of forming the mesa 10, the etching is stopped in the middle of the electric field control layer 30. When the electric field control layer 30 is thin, it is difficult to control the etching stop position. As the electric field control layer 30 is thicker, it is easier to control the etching stop position. The thickness T1 of the electric field control layer 30 may be 0.06 times or more the etching depth t shown in FIG. 2B. The etching depth t is, for example, 900 nm. The thickness T1 of the electric field control layer 30 is 0.06×t (=54 nm) or more, and is, for example, 200 nm. The etching stop position may be easily controlled. By increasing the thickness of the electric field control layer 30, the influence of unintended impurities may be reduced.

However, when the electric field control layer 30 is too thick, thermal excitation of carriers may occur in the depleted electric field control layer 30, and the dark current may increase. The traveling distance of the carrier increases, and the response speed decreases. In order to deplete the thick electric field control layer 30, the operating voltage is increased, and the power consumption increases. The electric field applied to the electron multiplication layer 28 increases before the electric field control layer 30 is depleted, and abnormal breakdown may occur. The thickness T1 of the electric field control layer 30 is set to 0.06×t or more and 500 nm or less, for example. The etching depth t is easily controlled. The dark current and the power consumption are less likely to increase. The response speed is improved. The thickness T1 of the electric field control layer 30 may be, for example, 0.06 t or more, 0.07 t or more, 0.8 t or more, or 1.0 t or more, and may be 400 nm or less, 500 nm or less, or 600 nm or less. When the variation in the etching depth in the wafer surface is large, the thickness T1 of the electric field control layer 30 is increased. The etching may be stopped in the middle of the electric field control layer 30.

The electric field control layer 30 is formed of the same material as the window layer 32 and the window layer 34. In the etching of the step of forming the mesa 10, the etching is stopped in the middle of the electric field control layer 30. Since the electric field control layer 30 is sufficiently thick, the etchant does not need to have selectivity when wet etching is used to form the mesa 10. An etchant with small anisotropy, such as an aqueous solution containing HBr, may be used. Since the anisotropy of etching is small, the inverted mesa shape is less likely to appear on the side surface of the mesa. In the inverted mesa shape, the electric field tends to concentrate at the root of the mesa. Since the mesa does not have an inverted mesa shape, the concentration of the electric field on the root of the mesa may be avoided. An increase in dark current and abnormal breakdown due to electric field concentration may be avoided.

### Modification 1

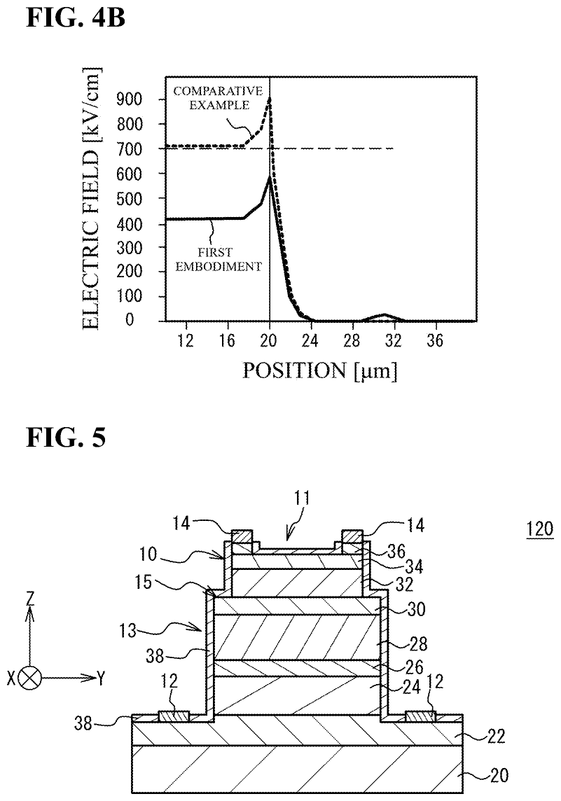

FIG. 5 is a cross-sectional view illustrating a light receiving element 120 according to modification 1. The description of the same configuration as that of the first embodiment will be omitted. The entire electric field control layer 30 is included in the mesa 13. The mesa 10 does not include the electric field control layer 30, but includes the window layer 32 and the window layer 34.

According to modification 1, the electric field is confined by the mesa 10. Since the electric field applied to the side surface of the mesa 13 is lowered, the dark current may be reduced and abnormal breakdown may be avoided. It is necessary that the etching to be stopped at the interface between the electric field control layer 30 and the window layer 32. The etching depth may vary. Even when the electric field control layer 30 is partially etched, the electric field control layer 30 is partially included in the mesa 10 as shown in FIG. 1B. It is necessary that the etching to be stopped before reaching the electron multiplication layer 28.

### Modification 2

The shape and method of manufacturing of the light receiving element are the same as those of the first embodiment. The substrate 20, the contact layer 22, the light-absorbing layer 24, and the contact layer 36 have the same structure as those of the first embodiment. The description of the same configuration as that of the first embodiment will be omitted. In modification 2, a part of the light receiving element is formed of another material.

The electric field control layer 26 may be formed of, for example, p-type aluminum gallium arsenide antimonide (p-AlₓGa₁₋ₓAs_{y}Sb_{1-y}, x=0.85, y=0.56). The electron multiplication layer 28 may be formed of, for example, AlₓGa₁₋ₓAs_{y}Sb_{1-y} (x=0.85, y=0.56). The electric field control layer 30 may be formed of, for example, n-AlₓGa₁₋ₓAs_{y}Sb_{1-y} (x=0.85, y=0.56). The window layer 32 and the window layer 34 may be formed of, for example, n-AlₓGa₁₋ₓAs_{y}Sb_{1-y} (x=0.85, y=0.56). The thickness and doping concentration of each layer may be the same as the thickness and doping concentration in the first embodiment.

The electric field control layer 26 and the electric field control layer 30 may be formed of InAlAs or AlGaAsSb, or may be formed of InP, indium aluminum arsenide antimonide (InAlAsSb), aluminum arsenide antimonide (AlAsSb), or aluminum gallium indium arsenide (AlGaInAs). The electric field control layer 26 and the electric field control layer 30 may be bulk semiconductors or superlattice layers of the above semiconductors.

### Second Embodiment

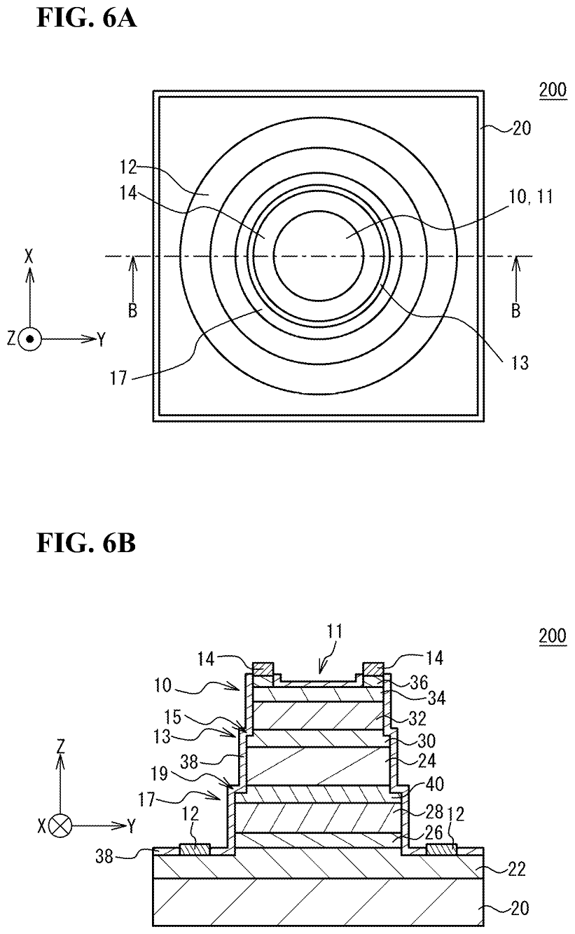

FIG. 6A is a plan view illustrating a light receiving element 200 according to a second embodiment. FIG. 6B is a cross-sectional view illustrating the light receiving element 200 and showing the cross section taken along line B-B of FIG. 6A. The description of the same configuration as that of the first embodiment will be omitted.

As shown in FIG. 6A, the light receiving element 200 includes the mesa 10 (first mesa), the mesa 13 (second mesa), and a mesa 17 (third mesa). That is, the light receiving element 200 has a three-stage mesa structure. The planar shapes of the mesa 10, the mesa 13, and the mesa 17 are circular, and are arranged concentrically in plan view. The width of the mesa 17 is greater than the width of mesa 10 and the width of the mesa 13. The mesa 17 is provided from below the mesa 10 and the mesa 13 to the outside of the mesa 13.

As shown in FIG. 6B, the light receiving element 200 includes the substrate 20, the contact layer 22 (first semiconductor layer), the electric field control layer 26 (second electric field control layer), the electron multiplication layer 28, an electric field control layer 40 (third electric field control layer), the light-absorbing layer 24, the electric field control layer 30 (first electric field control layer), the window layer 32 (second semiconductor layer), the window layer 34 (second semiconductor layer), and the contact layer 36.

The electric field control layer 26, the electron multiplication layer 28, and the electric field control layer 40 are stacked in this order in the central portion of the contact layer 22. The central portion of the electric field control layer 40 protrudes in the Z-axis direction from the outer peripheral portion of the electric field control layer 40. The light-absorbing layer 24 and the electric field control layer 30 are stacked in this order in the central portion of the electric field control layer 40. The central portion of the electric field control layer 30 protrudes in the Z-axis direction from the outer peripheral portion of the electric field control layer 30. The window layer 32 and the window layer 34 are stacked in the central portion of the electric field control layer 30. The ring-shaped contact layer 36 is provided on the upper surface of the window layer 34.

A portion of the electric field control layer 30 protruding in the Z-axis direction, the window layer 32, and the window layer 34 form the mesa 10. A part of the electric field control layer 40 in the Z-axis direction, the light-absorbing layer 24, and a part of the electric field control layer 30 in the Z-axis direction form the mesa 13. The protruding portion of the contact layer 22, the electric field control layer 26, the electron multiplication layer 28, and another part of the electric field control layer 40 form the mesa 17. The step portion 15 is formed in the electric field control layer 30 between the mesa 10 and the mesa 13. A step portion 19 is formed in the electric field control layer 26 between the mesa 13 and the mesa 17.

The substrate 20 is formed of, for example, n-type (first conductivity type) InP. The substrate 20 has a thickness of, for example, 500 μm. The contact layer 22 is formed of, for example, n-InₓGa₁₋ₓAs (x=0.53). The contact layer 22 has a thickness of, for example, 1000 nm. The electric field control layer 26 is formed of, for example, n-In_{y}Al_{1-y}As (y=0.52). The electric field control layer 26 has a thickness of, for example, 500 nm. The doping concentration of the n-type dopant in each of the substrate 20, the contact layer 22, and the electric field control layer 26 is, for example, 1.0×10¹⁸ cm⁻³. The electron multiplication layer 28 is formed of, for example, In_{y}Al_{1-y}As (y=0.52). The electron multiplication layer 28 has a thickness of, for example, 500 nm.

The electric field control layer 40 is formed of, for example, p-type (second conductivity type) In_{y}Al_{1-y}As (y=0.52). The electric field control layer 40 has a thickness of, for example, 250 nm. The doping concentration of the electric field control layer 40 is, for example, 1.5×10¹⁷ cm⁻³. The light-absorbing layer 24 is formed of, for example, InₓGa₁₋ₓAs (x=0.53). The light-absorbing layer 24 has a thickness of, for example, 1000 nm.

The electric field control layer 30 is formed of, for example, p-In_{y}Al_{1-y}As (y=0.52). The electric field control layer 30 has a thickness of, for example, 200 nm. The doping concentration of the electric field control layer 30 is, for example, 5.0×10¹⁶ cm⁻³.

The electric field control layer 30, the window layer 32, and the window layer 34 are formed of, for example, p-In_{y}Al_{1-y}As (y=0.52). The window layer 32 and the window layer 34 are formed of, for example, p-InₓGa₁₋ₓAs (x=0.52). The window layer 32 has a thickness of, for example, 600 nm. The window layer 34 has a thickness of, for example, 200 nm. The doping concentration of the window layer 32 and the window layer 34 is, for example, 1.0×10¹⁵ cm⁻³. The contact layer 36 is formed of, for example, p-InₓGa₁₋ₓAs (x=0.53). The contact layer 36 has a thickness of, for example, 200 nm. The doping concentration of the contact layer 36 is, for example, 1.0×10¹⁸ cm⁻³.

On one surface of the substrate 20, the contact layers are epitaxially grown from the contact layer 22 to the contact layer 36. The contact layer 36 is shaped into a ring shape. The mesa 10 is formed by etching from the window layer 34 to the middle of the electric field control layer 30. In a portion outside the mesa 10, the mesa 13 is formed by etching the electric field control layer 40 to the middle thereof. In a portion of the electric field control layer 40 outside the mesa 13, the mesa 17 is formed by etching the contact layer 22 to the middle thereof.

According to the second embodiment, the electric field control layer 30 is formed of the same material as the window layer 32 and the window layer 34. Since lattice distortion is less likely to occur, the dark current may be reduced.

As shown in FIG. 6B, the electric field control layer 26, the electron multiplication layer 28, and the electric field control layer 40 are stacked in this order between the contact layer 22 and the light-absorbing layer 24. A part of the electric field control layer 30, the window layer 32 and the window layer 34 form the mesa 10. A part of the electric field control layer 40, the light-absorbing layer 24, and another part of the electric field control layer 30 form the mesa 13. A part of the contact layer 22, the electric field control layer 26, the electron multiplication layer 28, and another part of the electric field control layer 40 form the mesa 17. The electric field is confined by the mesa 13 and the mesa 10. The mesa 13 is closer to the electron multiplication layer 28 than the mesa 10. Immediately after the depletion starts, the electric field is confined by the mesa 13. The electric field applied to the side surface of the electron multiplication layer 28 is lowered. Abnormal breakdown may be avoided.

In the example of FIG. 6B, a part of the electric field control layer 40 is included in the mesa 13. Another part of the electric field control layer 40 is included in the mesa 17. The entire electric field control layer 40 may be included in the mesa 17. It is necessary that the side surface of the mesa 13 does not reach the electron multiplication layer 28. The electric field applied to the side surface of the electron multiplication layer 28 is lowered. Abnormal breakdown may be avoided.

From the contact layer 36 to the electric field control layer 30 are p-type semiconductor layers. The light-absorbing layer 24 is an undoped semiconductor layer. The electric field control layer 26 and the contact layer 22 are n-type semiconductor layers. A positive-intrinsic-negative (pin) junction is formed along the Z axis. The semiconductor layer is depleted by the application of the voltage. The carriers travel by the electric field and are output as a photocurrent. Near the center of the light receiving element 200, a high electric field is applied to the electron multiplication layer 28, and thus avalanche breakdown is likely to occur. Sensitivity is improved.

### Modification 3

The shape and method of manufacturing of the light receiving element are the same as those of the first embodiment. The substrate 20, the contact layer 22, the light-absorbing layer 24, and the contact layer 36 have the same structure as those of the second embodiment. In modification 3, a part of the light receiving element is formed of another material.

The electric field control layer 26 may be formed of, for example, n-AlₓGa₁₋ₓAs_{y}Sb_{1-y} (x=0.85, y=0.56). The electron multiplication layer 28 may be formed of, for example, AlₓGa₁₋ₓAs_{y}Sb_{1-y} (x=0.85, y=0.56). The electric field control layer 40 and the electric field control layer 30 may be formed of, for example, p-AlₓGa₁₋ₓAs_{y}Sb_{1-y} (x=0.85, y=0.56). The window layer 32 and the window layer 34 may be formed of, for example, p-AlₓGa₁₋ₓAs_{y}Sb_{1-y} (x=0.85, y=0.56). The thickness and doping concentration of each layer are the same as the thickness and doping concentration in the second embodiment.

The first embodiment and the second embodiment may be applied to an array-type light receiving element. In the array-type light receiving element, a plurality of mesas is arranged in a two-dimensional grid, for example. A pair of one mesa 10 and one mesa 13 functions as one photodiode. The photodiodes are separated from each other by the recesses between the mesas. The first embodiment or the second embodiment is applied to each of the plurality of mesas.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving element comprising:
a first semiconductor layer having a first conductivity type;
a second semiconductor layer stacked on the first semiconductor layer and having a second conductivity type;
a light-absorbing layer provided between the first semiconductor layer and the second semiconductor layer;
a multiplication layer provided between the first semiconductor layer and the second semiconductor layer; and
a first electric field control layer provided between the light-absorbing layer and the second semiconductor layer and between the multiplication layer and the second semiconductor layer, and having the second conductivity type,
wherein the first electric field control layer is formed of the same material as the second semiconductor layer,
wherein the second semiconductor layer forms a first mesa,
wherein at least a part of the first electric field control layer in a thickness direction and the light-absorbing layer form a second mesa,
wherein the second mesa protrudes from the first semiconductor layer in the thickness direction,
wherein the first mesa protrudes from the second mesa in the thickness direction, and
wherein the second mesa is located below the first mesa and has a side surface located outside the first mesa in a plan view.

2. The light receiving element according to claim 1,
wherein a part of the first electric field control layer in the thickness direction and the second semiconductor layer form the first mesa, and
wherein another part of the first electric field control layer in the thickness direction and the light-absorbing layer form the second mesa.

3. The light receiving element according to claim 1, further comprising:
a second electric field control layer having the first conductivity type,
wherein the second electric field control layer, the multiplication layer, and the first electric field control layer are stacked in this order between the light-absorbing layer and the second semiconductor layer, and
wherein the light-absorbing layer, the second electric field control layer, the multiplication layer, and the at least a part of the first electric field control layer, form the second mesa.

4. The light receiving element according to claim 1,
wherein the first electric field control layer has a doping concentration of 1.0×10¹⁸ cm⁻³ or less.

5. The light receiving element according to claim 1,
wherein the first electric field control layer has a thickness that is 0.06 or more times a thickness from an upper surface of the second semiconductor layer to a center of the first electric field control layer in the thickness direction.

6. The light receiving element according to claim 1,
wherein the first conductivity type is a p-type, and
wherein the second conductivity type is an n-type.

7. The light receiving element according to claim 1, further comprising:
a third electric field control layer having the second conductivity type,
wherein the multiplication layer and the third electric field control layer are stacked in this order between the first semiconductor layer and the light-absorbing layer,
wherein the first electric field control layer is provided between the light-absorbing layer and the second semiconductor layer,
wherein at least a part of the third electric field control layer and the multiplication layer form a third mesa,
wherein the second mesa protrudes from the third mesa in the thickness direction, and
wherein the third mesa is located below the second mesa and has a side surface located outside the second mesa in a plan view.

8. The light receiving element according to claim 7,
wherein a part of the third electric field control layer in the thickness direction, the light-absorbing layer, and the at least a part of the first electric field control layer form the second mesa, and
wherein another part of the third electric field control layer in the thickness direction and the multiplication layer form the third mesa.

9. The light receiving element according to claim 7,
wherein the first conductivity type is an n-type, and
wherein the second conductivity type is a p-type.

10. A method of manufacturing a light receiving element, the method comprising:
growing a first semiconductor layer, a light-absorbing layer, a multiplication layer, an electric field control layer, and a second semiconductor layer;
forming a first mesa by etching the second semiconductor layer; and
forming a second mesa by etching the electric field control layer and the light-absorbing layer,
wherein the first semiconductor layer has a first conductivity type,
wherein the electric field control layer and the second semiconductor layer each have a second conductivity type,
wherein the electric field control layer is provided between the light-absorbing layer and the second semiconductor layer and between the multiplication layer and the second semiconductor layer, and is formed of the same material as the second semiconductor layer,
wherein the second semiconductor layer forms the first mesa,
wherein at least a part of the electric field control layer in a thickness direction and the light-absorbing layer form the second mesa,
wherein the first mesa protrudes from the second mesa in the thickness direction, and
wherein the second mesa is located below the first mesa and has a side surface located outside the first mesa in a plan view.
